(19) United States
(12) Patent Application Publication
(10) Pub. No.: US 2017/0103887 A1
(43) Pub. Date: Apr. 13, 2017

(54) METHOD FOR FORMING EPITAXIAL LAYER

(71) Applicant: ZING SEMICONDUCTOR CORPORATION, Shanghai (CN)

(72) Inventors: DEYUAN XIAO, Shanghai (CN); RICHARD R. CHANG, Shanghai (CN)

(21) Appl. No.: 15/134,722

(22) Filed: Apr. 21, 2016

(30) Foreign Application Priority Data
Oct. 12, 2015 (CN) 201510658742.8

(51) Int. Cl. H01L 21/02; H01L 21/311

(52) U.S. Cl. CPC H01L 21/0262; H01L 21/02381; H01L 21/02532; H01L 21/02598; H01L 21/02057; H01L 21/31111; H01L 21/02658; H01L 21/02634

(57) ABSTRACT

This invention provides a method for forming an epitaxial layer comprising, during formation of the epitaxial layer by vapor phase deposition, introducing a carrier gas containing deuterium. Because of the deuterium atmosphere, the deuterium atoms are introduced in the silicon epitaxial film. During formation of the gate oxide or device, the deuterium atoms are out-diffusion into the interface and covalently bound to the dangling bond to form stable structures. Accordingly, hot carrier effects can be prevented and the properties of the device can be enhanced.

### BACKGROUND OF THE INVENTION

1. Field of the Invention

The present application relates to a semiconductor manufacture, and more particularly to a method of formation of epitaxial layer.

2. Description of the Related Art

In the technical field of semiconductor manufacture, a layer of monocrystalline silicon is generally formed as the epitaxial layer on the silicon substrate. The epitaxial layer can undergo ion implantation doping to form collector region, emitter region and the like.

Challenges for epitaxial layer quality are increasing with the tendency of size reduction of microelectronic devices. The epitaxial layer quality depends on size and distribution of microdefects grown therein. During the formation of the epitaxial layer, most of the microdefects cluster among the silicon-vacancies or fill within the spaces.

Hydrogen passivation has become a well-known and established practice in the fabrication of semiconductor devices. In the hydrogen passivation process, defects which affect the operation of semiconductor devices are removed. For example, such defects have been described as recombination/generation centers on active components of semiconductor devices. These centers are thought to be caused by dangling bonds, which introduce states in the energy gap which remove charged carriers or add unwanted charge carriers in the device, depending in part on the applied bias. While dangling bonds occur primarily at surfaces or interfaces in the device, they also are thought to occur at vacancies, micropores, dislocations, and also to be associated with impurities.

Another problem which has arisen in the semiconductor industry, is the degradation of device performance by hot carrier effects. This is particularly of concern with respect to smaller devices in which proportionally larger voltages are used. When such high voltages are used, channel carriers can be sufficiently energetic to enter an insulating layer and degrade device behavior.

Since hydrogen passivation is not stable enough, its bonding with the dangling bond is broken easily. Therefore, the dangling bond is exposed again to adversely affect the properties of the device.

### SUMMARY

The purpose of the present application is to provide a method for forming an epitaxial layer, which is able to reduce the dangling bonds of the interface layers of a device and enhance the device properties.

For the above purposes, the present application provides a method for forming an epitaxial layer comprising: providing a silicon substrate, and forming an epitaxial layer on the silicon substrate by vapor phase deposition, in which a carrier gas containing deuterium is used.

In the method for forming an epitaxial layer, a temperature of 800° C.-1100° C. is applied for the vapor phase deposition.

In the method for forming an epitaxial layer, the carrier gas of the vapor phase deposition is a mixture of deuterium and hydrogen

In the method for forming an epitaxial layer, the deuterium is 1%-100% of the gas mixture.

In the method for forming an epitaxial layer, the carrier gas of the vapor phase deposition is deuterium.

In the method for forming an epitaxial layer, the epitaxial layer is monocrystalline silicon.

In the method for forming an epitaxial layer, the reaction gas used in the vapor phase deposition is a gas containing a silicon atom.

In the method for forming an epitaxial layer, the reaction gas used in the vapor phase deposition contains SiH₄, Si₂H₆, SiH₂Cl₂, SiHCl₃, SiCl₄ or Si(CH₃)₄.

In the present application, after providing the silicon substrate and before forming the epitaxial layer, the method further comprises: removing a native oxide layer on the silicon substrate surface, and washing the silicon substrate.

In the method for forming an epitaxial layer, the native oxide layer on the silicon substrate surface is removed by wet etching or dry etching.

The method of the present application is advantageous over the prior art. Because of the deuterium atmosphere provided by the carrier gas containing deuterium, the deuterium atoms are introduced in the silicon epitaxial film. During formation of the gate oxide or the device, the deuterium atoms are out-diffusion into the interface and covalently bound to the dangling bonds at the interface to form stable structures. Accordingly, hot carrier effects can be prevented and the properties of the device can be enhanced.

### BRIEF DESCRIPTION OF THE DRAWINGS

FIG. 1 shows one embodiment of the method for forming the pitaxy layer.

### DETAILED DESCRIPTION OF THE EMBODIMENTS

Although the following with reference to the accompanying drawings of the method of the present invention is further described in more detail, there is shown a preferred embodiment of the present invention. A person having ordinary skills in the art may modify the invention described herein while still achieving the advantageous effects of the present invention. Thus, these embodiments should be understood as broad, teaching one skilled in the art, and not as a limitation of the present invention.

For purpose of clarity, not all features of an actual embodiment are described. It may not describe the well-known functions as well as structures in detail to avoid confusion caused by unnecessary details. It should be considered that, in the developments of any actual embodiment, a large number of practice details must be made to achieve the specific goals of the developer, for example, according to the requirements or the constraints of the system or the commercials, one embodiment is changed to another. In addition, it should be considered that such a development effort might be complex and time-consuming, but for a person having ordinary skills in the art is merely routine work.

In the following paragraphs, the accompanying drawings are referred to describe the present invention more specifically by way of example. The advantages and the features of the present invention are more apparent according to the following description and claims. It should be noted that the drawings are in a simplified form with non-precise ratio for the purpose of assistance to conveniently and clearly explain an embodiment of the present invention.

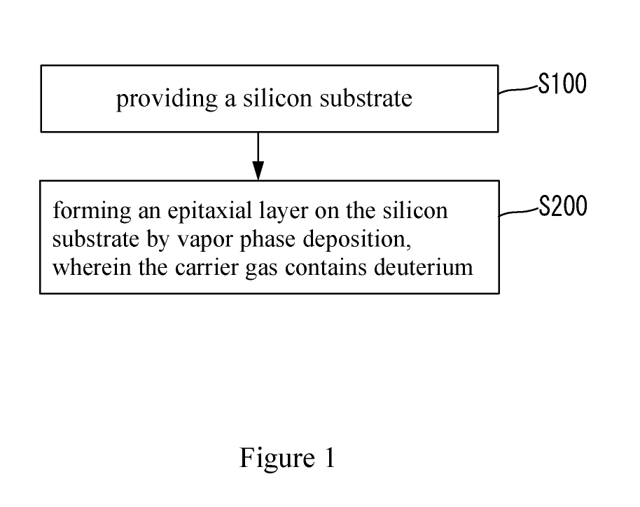

In one embodiment, referring to FIG. 1, the method for forming the epitaxial layer comprises the following steps:

S100: providing a silicon substrate,
S200: forming an epitaxial layer on the silicon substrate by vapor phase deposition, and, in this step, a carrier gas containing deuterium is applied.

In one embodiment, the silicon substrate can be formed by the following steps. First, an silicon ingot is formed and polished to a desired size such as the size of a wafer. Then the steps including slicing, surface grinding, polishing, edge profiling and cleaning are applied to form the silicon substrate. In the present embodiment, the silicon substrate is monocrystalline silicon formed by Czochralski (CZ) method.

Between the steps of providing the silicon substrate and forming the epitaxial layer, the following steps are applied. A native oxide layer on the silicon substrate surface is removed by such as wet etching or dry etching. Generally, during long-term exposure under the air, the silicon substrate is oxidized by the oxygen of the air, and a thin native oxide layer is formed accordingly. Removal of the native oxide layer makes the good contact between the silicon substrate and the epitaxial layer, and improves the quality of the silicon substrate. Then, the silicon substrate is washed.

In S200, the vapor phase deposition is applied to form the epitaxial layer. The carrier gas used in the vapor phase deposition includes deuterium.

In one embodiment, the temperature of the vapor phase deposition is 800° C.-1100° C., such as 1000° C.

In the present example, the carrier gas of the vapor phase deposition is a mixture of deuterium and hydrogen. The deuterium is 1%-100% of the gas mixture, which can be adjusted according to different process requirements.

In one embodiment, the carrier gas of the vapor phase deposition can be deuterium solely.

While using deuterium as the carrier gas to form the epitaxial layer, deuterium is able to be temporarily stored in the gap of the epitaxial layer because of the small size of the deuterium atom. In the following process for forming a gate oxide layer or a device, the stored deuterium atoms can combine to dangling bonds of the gate oxide layer to form stable chemical bonds. Accordingly, the redundant dangling bonds can be eliminated, and the properties of the gate oxide layer can be enhanced thereby. Moreover, the deuterium atoms not only combine to the dangling bonds of the gate oxide layer but also the dangling bonds of other layers of the semiconductor device. The formed chemical bond from deuterium is more stable than that from other elements such as hydrogen atom.

In the present example, the epitaxial layer is monocrystalline silicon. The reaction gas used in the vapor phase deposition is a gas containing a silicon atom. For example, a gas containing SiH4, Si2H6, SiH2Cl2, SiHCl3, SiCl4 or Si(CH3)4 can be applied alone or in combination. The thickness of the epitaxial layer is not limited herein, which can be decided according to the applied process.

Accordingly, in the examples of the present application, the carrier gas containing deuterium is applied in the vapor phase deposition to form the epitaxial layer. Because of the deuterium atmosphere, the deuterium atoms are introduced in the epitaxial layer. During formation of the gate oxide layer or the device, the deuterium atoms are out-diffusion into the interface and covalently bound to the dangling bonds to form the more stable structures. Accordingly, hot carrier effects can be prevented and the properties of the device can be enhanced.

Realizations of the above method have been described in the context of particular embodiments. These embodiments are meant to be illustrative and not limiting. Many variations, modifications, additions, and improvements are possible. These and other variations, modifications, additions, and improvements may fall within the scope of the invention as defined in the claims that follow.

1. A method for forming an epitaxial layer characterized by comprising the following steps:
providing a silicon substrate, and
forming an epitaxial layer on the silicon substrate by vapor phase deposition under a carrier gas containing deuterium.

2. The method of claim 1, wherein the vapor phase deposition is performed at 800-1100.

3. The method of claim 1, wherein the carrier gas is a mixture of deuterium and hydrogen.

4. The method of claim 3, wherein the deuterium is 1%-100% of the gas mixture.

5. The method of claim 1, wherein the carrier gas is deuterium.

6. The method of claim 1, wherein the epitaxial layer is monocrystalline silicon.

7. The method of claim 6, wherein the vapor phase deposition applies a reaction gas containing a silicon atom.

8. The method of claim 7, wherein the reaction gas contains SiH4, Si2H6, SiH2Cl2, SiHCl3, SiCl4 or Si(CH3)4.

9. The method of claim 1, which further comprises the following steps between the steps of providing the silicon substrate and forming the epitaxial layer:
removing a native oxide layer on the silicon substrate surface, and
washing the silicon substrate.

10. The method of claim 9, wherein the native oxide layer on the silicon substrate surface is removed by wet etching or dry etching.
